(19) United States
(12) Patent Application Publication
(10) Pub. No.: US 2010/0007022 A1
(43) Pub. Date: Jan. 14, 2010

(54) SEMICONDUCTOR DEVICE AND MANUFACTURING METHOD THEREOF

(76) Inventors: Nobuaki Tarumi, Ibaraki (JP); Shinichi Ogawa, Ibaraki (JP)

Correspondence Address: MCDERMOTT WILL & EMERY LLP, 600 13TH STREET, NW, WASHINGTON, DC, 20005-3096, US

(21) Appl. No.: 12/518,611

(22) PCT Filed: Jul. 29, 2008
(86) PCT No.: PCT/JP2008/002019

§ 371 Date: Jun. 10, 2009

(30) Foreign Application Priority Data
Aug. 3, 2007 (JP) 2007-202965

(51) Int. Cl. H01L 23/522; H01L 21/768

(52) U.S. Cl. 257/751; 438/643; 257/E23.142; 257/E21.584

(57) ABSTRACT

A semiconductor device includes an insulating film formed on a semiconductor substrate, and a buried interconnect formed in the insulating film and made of copper or a copper alloy. A barrier metal layer made of a platinum group element or a platinum group element alloy is formed between the insulating film and the buried interconnect, and the barrier metal layer partially includes an amorphous structure having a degree of amorphousness that provides a relatively high barrier property.

### TECHNICAL FIELD

The invention relates to a semiconductor device having a copper interconnect or a copper alloy interconnect and a manufacturing method thereof.

### BACKGROUND ART

Patent Document 1 describes the use of a metal such as ruthenium which does not lose its conductivity even when being oxidized and a conductive metal oxide film as a barrier metal.

Hereinafter, a conventional manufacturing method of a semiconductor device will be described with reference to FIGS. 8(a) through 8(e) by taking as an example a copper interconnect manufacturing technique using ruthenium as a barrier metal film (for example, see Patent Document 1).

First, as shown in FIG. 8(a), a first interconnect 803 made of, for example, a copper film is buried in a first insulating film 801 on a semiconductor substrate 800 through a first barrier metal 802 made of, for example, a ruthenium film. A first silicon nitride film 804 and a second insulating film 805 are then sequentially deposited over the semiconductor substrate 800, and a via hole 806 and an interconnection groove 807 are formed in the first silicon nitride film 804 and the second insulating film 805 so as to reach the first interconnect 803. At this time, the first barrier metal 802 or the first silicon nitride film 804 prevents copper atoms of the first interconnect 803 from diffusing into the first insulating film 801, the second insulating film 805 or the like by heat treatment at about 400° C. for depositing the second insulating film 805 (for example, a plasma CVD (Chemical Vapor Deposition) method). In other words, the first barrier metal 802 or the first silicon nitride film 804 has a barrier property against copper atom diffusion.

As shown in FIG. 8(b), a second barrier metal 808 made of ruthenium is then deposited with a thickness of 10 nm over the semiconductor substrate 800 by, for example, a sputtering method.

Thereafter, a copper seed layer 809 made of a copper film is deposited with a thickness of 30 nm on the second barrier metal 808 by, for example, a sputtering method. Respective bottoms and sidewalls of the via hole 806 and the interconnection groove 807 are thus covered by the second barrier metal 808 and the copper seed layer 809.

As shown in FIG. 8(c), a copper plating layer 810 is then grown with a thickness of 300 nm on the copper seed layer 809 by an electroplating method so as to fill the via hole 806 and the interconnection groove 807.

Thereafter, the semiconductor substrate 800 is removed from a plating apparatus, and the copper plating layer 810 is heat treated (for example, at about 100° C. for about 2 hours) in order to grow crystal grains of the copper plating layer 810. As a result, as shown in FIG. 8(d), the copper seed layer 809 and the copper plating layer 810 are integrated to form an interconnection copper film 811. Note that, instead of performing the above-described heat treatment to the copper plating layer 810, the semiconductor substrate 800 may be left at room temperature for about two days.

As shown in FIG. 8(e), the second barrier metal 808 and interconnection copper film 811 located outside the interconnection groove 807 are removed by, for example, a CMP (Chemical Mechanical Polishing) method to form a via 812 and a second interconnect 813 from the interconnection copper film 811. The first interconnect 803 and the second interconnect 813 are thus connected to each other through the via 812.

Although not shown in the figure, a desired multilayer interconnect structure is formed as necessary by repeating the process described using the cross-sectional views of FIGS. 8(a) through 8(e) (regarding the process described using the cross-sectional view of FIG. 8(a), the step of depositing the first silicon nitride film 804 and the following steps).

[Patent Document 1] Japanese Laid-Open Patent Publication No. 2002-075994

### DISCLOSURE OF THE INVENTION

### Problems to be Solved by the Invention

However, when a conductive metal or a metal oxide film or ruthenium, rhenium, or an alloy thereof is used as a barrier metal layer as described above, an adhesion property to copper is improved, while a barrier property required for a barrier metal is degraded.

In view of the above, it is an object of the invention to provide a barrier metal layer having a higher barrier property than that of the above-described barrier metal layer.

### Means for Solving the Problems

In order to solve the above problems, a semiconductor device according to one aspect of the invention includes: an insulating film formed on a semiconductor substrate; and a buried interconnect formed in the insulating film and made of copper or a copper alloy. A barrier metal layer made of a platinum group element or a platinum group element alloy is formed between the insulating film and the buried interconnect, and the barrier metal layer partially includes an amorphous structure having a degree of amorphousness that provides a relatively high barrier property.

In this structure, the barrier metal layer made of a platinum group element or a platinum group element alloy is formed between the insulating film and the buried interconnect, and the barrier metal layer partially includes an amorphous structure having a relatively high barrier property. Since this barrier metal layer includes an amorphous structure, the barrier metal layer has less grain boundary than that of a polycrystalline structure, which is very effective to suppress diffusion of copper through the barrier metal layer. Moreover, since a platinum group metal or a platinum group element alloy has a low specific resistance, increase in interconnect resistance and via resistance can be prevented. Moreover, since a platinum group metal or a platinum group element alloy has a high melting point, excellent thermal stability is obtained.

In the semiconductor device according to the one aspect of the invention, the barrier metal layer may be a single layer.

In the semiconductor device according to the one aspect of the invention, the barrier metal layer may have a layered structure and may have a layer partially including the amorphous structure and a polycrystalline structure layer. The layer partially including the amorphous structure and the polycrystalline structure layer may be sequentially formed in this order in a direction from the insulating film toward the buried interconnect.

In this case, the layered barrier metal layer made of a platinum group element or a platinum group element alloy is formed between the insulating film and the buried interconnect, and the layered barrier metal layer has a layer partially including an amorphous structure having a relatively high barrier property and a polycrystalline structure layer. The layer partially including the amorphous structure has less grain boundary than that of a polycrystalline structure, which is very effective to suppress diffusion of copper through the barrier metal layer. Moreover, since a platinum group metal and a platinum group element alloy have a low specific resistance, increase in interconnect resistance and via resistance can be prevented. Moreover, since a platinum group metal and a platinum group element alloy have a high melting point, excellent thermal stability is obtained. Moreover, a layer having a polycrystalline structure of a platinum group element and a platinum group element alloy has an excellent adhesion property to an interconnect material such as copper, and therefore, has excellent wettability to copper and excellent burying characteristics. Moreover, since this layer has also an excellent oxidation resistance, the adhesion property is less likely to be degraded even when the metal surface is exposed to an oxidizing atmosphere during an interconnect formation process.

In the semiconductor device according to the one aspect of the invention, the barrier metal layer may be structured so that the degree of amorphousness that provides the relatively high barrier property is reduced stepwise in a direction from the insulating film toward the buried interconnect.

In this case, the barrier metal layer made of a platinum group element or a platinum group element alloy is formed between the insulating film and the buried interconnect, and the barrier metal layer is structured so that the degree of amorphousness that provides the relatively high barrier property is reduced stepwise. In other words, the barrier metal layer has a layer having a degree of amorphousness reduced stepwise from the value of the layer partially including the amorphous structure having the relatively high barrier property from the insulating film toward the buried interconnect. The layer partially including the amorphous structure has less grain boundary than that of a polycrystalline structure, which is very effective to suppress diffusion of copper through the barrier metal layer. Moreover, since a platinum group metal and a platinum group element alloy have a low specific resistance, increase in interconnect resistance and via resistance can be prevented. Moreover, since a platinum group metal and a platinum group element alloy have a high melting point, excellent thermal stability is obtained. Moreover, a layer having a reduced degree of amorphousness of a platinum group metal and a platinum group element alloy has an excellent adhesion property to an interconnect material such as copper, and therefore, has excellent wettability to copper and excellent burying characteristics. Moreover, since this layer has also an excellent oxidation resistance, the adhesion property is less likely to be degraded even when the metal surface is exposed to an oxidizing atmosphere during an interconnect formation process. Moreover, since a metal of the same kind of platinum group element is used in the barrier metal layer, an adhesion property within the barrier metal layer is improved.

In the semiconductor device according to the one aspect of the invention, the barrier metal layer may sequentially include a first polycrystalline structure layer, a layer partially including the amorphous structure, and a second polycrystalline structure layer in a direction from the insulating film toward the buried interconnect.

In this case, the barrier metal layer is formed on the buried interconnect and an interface between a layer partially including an amorphous structure and copper is not generated in a connection portion with the buried interconnect. Since a layer made of a polycrystalline structure of a platinum group element or a platinum group element alloy has higher activation energy than that of a layer partially including an amorphous structure, reliability can be improved.

In the semiconductor device according to the one aspect of the invention, the barrier metal layer may be structured so that a degree of amorphousness is increased stepwise from a value having a first polycrystalline structure to the value that provides the relatively high barrier property and reduced stepwise from the value that provides the relatively high barrier property to a value having a second polycrystalline structure in a direction from the insulating film toward the buried interconnect.

In this case, the barrier metal layer is formed on the buried interconnect and an interface between a layer partially including an amorphous structure and copper is not generated in a connection portion with the buried interconnect. Since a layer made of a polycrystalline structure of a platinum group element or a platinum group element alloy has higher activation energy than that of a layer partially including an amorphous structure, reliability can be improved.

In the semiconductor device according to the one aspect of the invention, it is desirable that the platinum group element is ruthenium, rhodium, palladium, osmium, iridium, or platinum.

A method for manufacturing a semiconductor device according to another aspect of the invention includes the steps of: (a) forming a recess in an insulating film on a semiconductor substrate; (b) depositing a barrier metal layer made of a platinum group element or a platinum group element alloy in the recess; (c) sequentially depositing a first conductive film made of copper or a copper alloy on the barrier metal layer; (d) growing a second conductive film made of copper or a copper alloy on the first conductive film so as to completely fill the recess; and (e) integrating the first conductive film and the second conductive film to form a third conductive film and forming a buried interconnect from the third conductive film, wherein the barrier metal layer partially includes an amorphous structure having a degree of amorphousness that provides a relatively high barrier property.

In this structure, the barrier metal layer containing a platinum group element or a platinum group element alloy can be formed in the recess. This is very effective to suppress diffusion of copper through the barrier metal layer. Moreover, since a platinum group metal or a platinum group element alloy has a low specific resistance, increase in interconnect resistance and via resistance can be prevented. Moreover, since a platinum group metal or a platinum group element alloy has a high melting point, excellent thermal stability is obtained.

In the method for manufacturing a semiconductor device according to the another aspect of the invention, the step (b) may include the steps of (b1) depositing in the recess a first barrier metal layer that forms the barrier metal layer and is made of a platinum group element or a platinum group element alloy, and (b2) depositing on the first barrier metal layer a second barrier metal layer that forms the barrier metal layer and is made of a platinum group element or a platinum group element alloy, wherein the first barrier metal layer may partially include the amorphous structure having the degree of amorphousness that provides the relatively high barrier property, and the second barrier metal layer may have a polycrystalline structure.

In this case, the layered barrier metal layer made of a platinum group element or a platinum group element alloy is formed in the recess, and the layered barrier metal layer includes a layer partially includes an amorphous structure having a relatively high barrier property and a layer of a polycrystalline structure. The layer partially including an amorphous structure has less grain boundary than that of the polycrystalline structure, which is very effective to suppress diffusion of copper through the barrier metal layer. Moreover, since a platinum group metal and a platinum group element alloy have a low specific resistance, increase in interconnect resistance and via resistance can be prevented. Moreover, since a platinum group metal and a platinum group element alloy have a high melting point, excellent thermal stability is obtained. Moreover, a layer having a polycrystalline structure of a platinum group element and a platinum group element alloy has an excellent adhesion property to an interconnect material such as copper, and therefore, has excellent wettability to copper and excellent burying characteristics. Moreover, since this layer has also an excellent oxidation resistance, the adhesion property is less likely to be degraded even when the metal surface is exposed to an oxidizing atmosphere during an interconnect formation process.

In the method for manufacturing a semiconductor device according to the another aspect of the invention, the step (b) may include the steps of (b1) depositing in the recess a first barrier metal layer that forms the barrier metal layer and is made of a platinum group element or a platinum group element alloy, (b2) depositing on the first barrier metal layer a second barrier metal layer that forms the barrier metal layer and is made of a platinum group element or a platinum group element alloy, and (b3) depositing on the second barrier metal layer a third barrier metal layer that forms the barrier metal layer and is made of a platinum group element or a platinum group element alloy, wherein the second barrier metal layer may partially include the amorphous structure having the degree of amorphousness that provides the relatively high barrier property, and the first barrier metal layer and the third barrier metal layer may have a polycrystalline structure.

In this case, the barrier metal layer is formed on the buried interconnect and an interface between a layer partially including an amorphous structure and copper is not generated in a connection portion with the buried interconnect. Since a layer made of a polycrystalline structure of a platinum group element and a platinum group element alloy has higher activation energy than that of a layer partially including an amorphous structure, reliability can be improved.

In the method for manufacturing a semiconductor device according to the another aspect of the invention, the step (b) may include the step of forming the barrier metal film so that the degree of amorphousness that provides the relatively high barrier property is reduced stepwise in a direction from the insulating film toward the buried interconnect.

In this case, a layer can be formed in the recess so that the degree of amorphousness that provides the relatively high barrier property is reduced stepwise in the direction from the insulating film toward the buried interconnect. In other words, a layer having a degree of amorphousness reduced stepwise from the value of the layer partially including the amorphous structure having the relatively high barrier property from the insulating film toward the buried interconnect can be formed in the recess. The layer partially including the amorphous structure has less grain boundary than that of a polycrystalline structure, which is very effective to suppress diffusion of copper through the barrier metal layer. Moreover, since a platinum group metal and a platinum group element alloy have a low specific resistance, increase in interconnect resistance and via resistance can be prevented. Moreover, since a platinum group metal and a platinum group element alloy have a high melting point, excellent thermal stability is obtained. Moreover, a layer having a reduced degree of amorphousness of a platinum group metal and a platinum group element alloy has an excellent adhesion property to an interconnect material such as copper, and therefore, has excellent wettability to copper and excellent burying characteristics. Moreover, since this layer has also an excellent oxidation resistance, the adhesion property is less likely to be degraded even when the metal surface is exposed to an oxidizing atmosphere during an interconnect formation process. Moreover, since a metal of the same kind of platinum group element is used in the barrier metal layer, an adhesion property within the barrier metal layer is improved.

In the method for manufacturing a semiconductor device according to the another aspect of the invention, the step (b) may include the step of forming the barrier metal film so that a degree of amorphousness is increased stepwise from a value having a first polycrystalline structure to the value that provides the relatively high barrier property and reduced stepwise from the value that provides the relatively high barrier property to a value having a second polycrystalline structure in a direction from the insulating film toward the buried interconnect.

In this case, the barrier metal layer is formed on the buried interconnect and an interface between a layer partially including an amorphous structure and copper is not generated in a connection portion with the buried interconnect. Since a layer made of a polycrystalline structure of a platinum group element and a platinum group element alloy has higher activation energy than that of a layer partially including an amorphous structure, reliability can be improved.

In the method for manufacturing a semiconductor device according to the another aspect of the invention, it is desirable that the platinum group element is ruthenium, rhodium, palladium, osmium, iridium, or platinum.

Since these platinum group metals have a low specific resistance, increase in interconnect resistance and via resistance can be prevented. Moreover, since these platinum group metals have a high melting point, excellent thermal stability is obtained. Moreover, polycrystalline metals of these platinum group elements have an excellent adhesion property to an interconnect material such as copper and also have an excellent oxidation resistance. Therefore, the adhesion property is less likely to be degraded even when the metal surface is exposed to an oxidizing atmosphere during an interconnect formation process.

In the method for manufacturing a semiconductor device according to the another aspect of the invention, the step (e) may include the step of performing heat treatment in a nitrogen atmosphere.

This can suppress crystallization of the barrier metal having an amorphous structure during the heat treatment, whereby loss of the barrier property can be reliably prevented.

In the method for manufacturing a semiconductor device according to the another aspect of the invention, the step (b) may be performed in a same chamber by using a sputtering method while controlling a nitrogen flow rate.

### EFFECTS OF THE INVENTION

As has been described above, a barrier metal containing a platinum group element or a platinum group element alloy and partially including an amorphous structure having a relatively high barrier property can provide a barrier metal having a higher barrier property than that of a conventional barrier metal, capable of preventing increase in interconnect resistance and via resistance, and having excellent thermal stability.

### BRIEF DESCRIPTION OF THE DRAWINGS

FIGS. 1(a) through 1(e) are cross-sectional views illustrating each step of a method for manufacturing a semiconductor device according to a first embodiment of the invention;

FIG. 2 is a graph common to each embodiment of the invention, illustrating a relation between a nitrogen partial pressure during barrier metal formation and a degree of amorphousness of a formed barrier metal;

FIG. 3 is a graph common to each embodiment of the invention, illustrating a relation between a nitrogen partial pressure during barrier metal formation and a degree of amorphousness of a barrier metal after heat treatment;

FIGS. 4(a) through 4(e) are cross-sectional views illustrating each step of a method for manufacturing a semiconductor device according to a second embodiment of the invention;

FIGS. 5(a) through 5(e) are cross-sectional views illustrating each step of a method for manufacturing a semiconductor device according to a third embodiment of the invention;

FIGS. 6(a) through 6(e) are cross-sectional views illustrating each step of a method for manufacturing a semiconductor device according to a fourth embodiment of the invention;

FIGS. 7(a) through 7(e) are cross-sectional views illustrating each step of a method for manufacturing a semiconductor device according to a fifth embodiment of the invention; and

FIGS. 8(a) through 8(e) are cross-sectional views illustrating each step of a conventional method for manufacturing a semiconductor device.

### DESCRIPTION OF THE REFERENCE NUMERALS

100 semiconductor substrate
101 first insulating film
102 first barrier metal
103 first interconnect
104 first silicon nitride film
105 second insulating film
106 via hole
107 interconnection groove
108 second barrier metal
109 copper seed layer
110 copper plating layer
111 interconnection copper film
112 via
113 second interconnect
400 semiconductor substrate
401 first insulating film
402 first barrier metal
403 second barrier metal
404 first interconnect
405 first silicon nitride film
406 second insulating film
407 via hole
408 interconnection groove
409 third barrier metal
410 fourth barrier metal
411 copper seed layer
412 copper plating layer
413 interconnection copper film
414 via
415 second interconnect
500 semiconductor substrate
501 first insulating film
502 first barrier metal
503 first interconnect
504 first silicon nitride film
505 second insulating film
506 via hole
507 interconnection groove
508 second barrier metal
509 copper seed layer
510 copper plating layer
511 interconnection copper film
512 via
513 second interconnect
600 semiconductor substrate
601 first insulating film
602 first barrier metal
603 first interconnect
604 first silicon nitride film
605 second insulating film
606 via hole
607 interconnection groove
608 second barrier metal
609 third barrier metal
610 fourth barrier metal
611 copper seed layer
613 copper plating layer
614 via
615 second interconnect
700 semiconductor substrate
701 first insulating film
702 first barrier metal
703 first interconnect
704 first silicon nitride film
705 second insulating film
706 via hole
707 interconnection groove
708 second barrier metal
709 copper seed layer
710 copper plating layer
711 interconnection copper film
712 via
713 second interconnect
800 semiconductor substrate
801 first insulating film
802 first barrier metal
803 first interconnect
804 first silicon nitride film
805 second insulating film
806 via hole
807 interconnection groove
808 second barrier metal
809 copper seed layer
810 copper plating layer
811 interconnection copper film
812 via
813 second interconnect

### BEST MODE FOR CARRYING OUT THE INVENTION

Hereinafter, embodiments of the invention will be described with reference to the accompanying drawings.

### First Embodiment

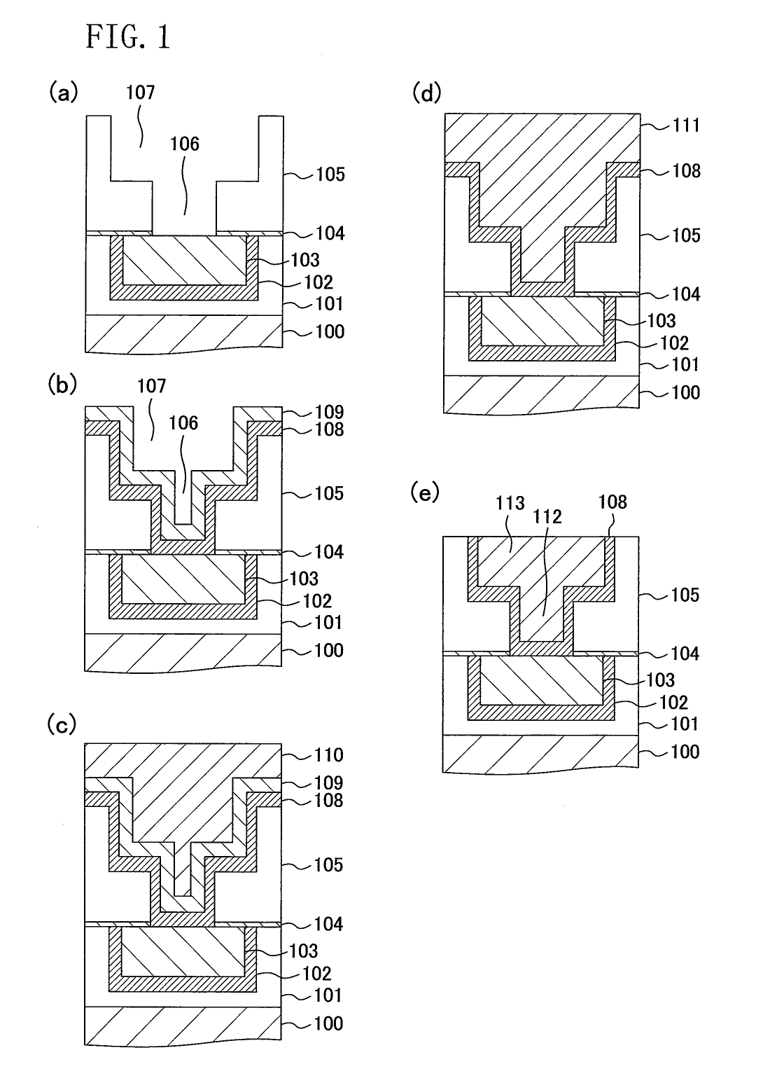

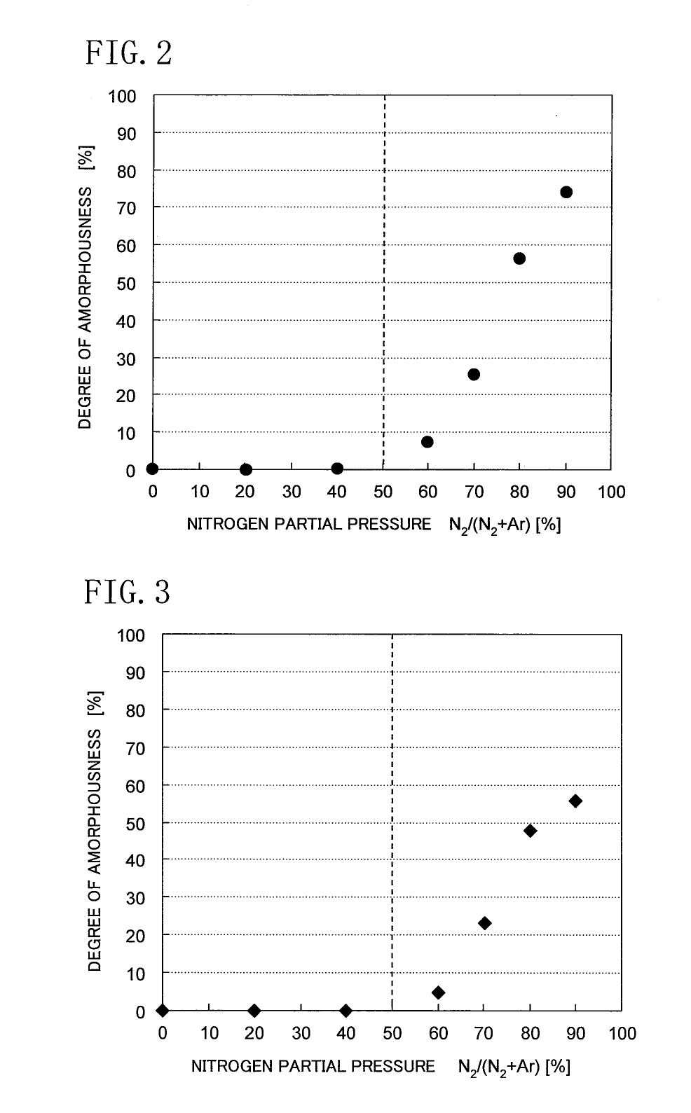

A first embodiment of the invention will now be described with reference to FIGS. 1(a) through 1(e), 2 and 3. FIGS. 1(a) through 1(e) are cross-sectional views illustrating each step of a method for manufacturing a semiconductor device according to the first embodiment of the invention. FIG. 2 is a graph common to each embodiment of the invention, illustrating a relation between a nitrogen partial pressure during barrier metal formation and a degree of amorphousness of a formed barrier metal. FIG. 3 is a graph common to each embodiment of the invention, illustrating a relation between a nitrogen partial pressure during barrier metal formation and a degree of amorphousness of a barrier metal after heat treatment.

First, as shown in FIG. 1(a), a first interconnect 103 made of, for example, a copper film is buried in a groove of a first insulating film 101 on a semiconductor substrate 100 through a first barrier metal 102 made of, for example, a ruthenium film. A first silicon nitride film 104 and a second insulating film 105 are then sequentially deposited over the semiconductor substrate 100, and a via hole 106 and an interconnection groove 107 are formed in the first silicon nitride film 104 and the second insulating film 105 so as to reach the first interconnect 103. At this time, the first barrier metal 102 or the first silicon nitride film 104 prevents copper atoms of the first interconnect 103 from diffusing into the first insulating film 101, the second insulating film 105 or the like by heat treatment at about 400° C. for depositing the second insulating film 105 (for example, a plasma CVD (Chemical Vapor Deposition) method). In other words, the first barrier metal 102 or the first silicon nitride film 104 has a barrier property against copper atom diffusion.

As shown in FIG. 1(b), a second barrier metal 108 made of a single layer of ruthenium is then deposited with a thickness of 10 nm over the semiconductor substrate 100 by, for example, a sputtering method. At this time, ruthenium is used as a sputtering target and nitrogen is contained in a sputtering atmosphere. As will be described in the experimental result below, the single-layer second barrier metal 108 partially including an amorphous structure preferably has a nitrogen concentration of 2% to 10%, and more preferably, 4% to 10%.

In FIG. 2, the abscissa indicates a nitrogen partial pressure, that is, [N₂]/([N₂]+[Ar]), during sputtering, and the ordinate indicates a degree of amorphousness of ruthenium. The degree of amorphousness will now be described. Provided that X is a crystal orientation intensity (for example, the sum of crystal orientation intensities) at a nitrogen partial pressure of 0% and Y is a crystal orientation intensity at a certain nitrogen partial pressure (Y is equal to or less than X), the degree of amorphousness is shown by [(X−Y)/X]×100 (%).

It can be seen from FIG. 2 that the degree of amorphousness increases with increase in the nitrogen partial pressure during sputtering. The crystal structure of ruthenium or a ruthenium alloy can therefore be easily controlled by controlling the nitrogen gas amount during sputtering. Although ruthenium was described herein, the same tendency is obtained for other platinum group elements and alloys of platinum group elements. By performing experiments to examine the relation between nitrogen partial pressure and nitrogen concentration after formation of a barrier metal film, the nitrogen concentration was 4%, 6%, and 8% when [N₂]/([N₂]+[Ar]) was 70%, 80%, and 90%, respectively. The nitrogen concentration is herein defined by (the number of nitrogen atoms in the barrier metal film)/(the number of atoms in the barrier metal film).

In FIG. 3, the abscissa indicates a nitrogen partial pressure, that is, [N₂]/([N₂]+[Ar]), during sputtering, and the ordinate indicates a degree of amorphousness of ruthenium after heat treatment. It can be seen from FIG. 3 that the degree of amorphousness does not become 0% even when heat treatment is performed, and the degree of amorphousness increases with increase in the nitrogen partial pressure during sputtering. The crystal structure of ruthenium can therefore be easily controlled by controlling the nitrogen gas amount during sputtering. Although ruthenium was described herein, the same tendency is obtained for other platinum group elements and alloys of platinum group elements.

In order to evaluate the barrier property, we also performed the following experiment: an interconnect pattern having a damascene structure was formed over a silicon substrate and a thermal oxide film was deposited in the interconnect pattern. A barrier metal was then deposited, a copper interconnect was formed by a damascene process, and an aluminum electrode was formed as an electrode. A voltage temperature test was then conducted by heating the silicon substrate to 50° C. and applying a voltage of 500 mV between the silicon substrate and the electrode and holding the silicon substrate for ten minutes. A change in capacitance of the thermal oxide film before and after the voltage temperature test was measured, and it was confirmed that the capacitance does not change when the barrier property is high. By evaluating the barrier property by this method, we found that, when the nitrogen partial pressure during sputtering is 50% or higher, the capacitance does not change and a high barrier property can be obtained.

It can be seen from the above results and the data of FIGS. 2 and 3 that a barrier metal including an amorphous structure having a high barrier property is formed when the nitride partial pressure during sputtering is 50% or higher. Note that the data shown herein was obtained using a sputtering apparatus made by Applied Materials, Inc., but it should be understood that data may be different from the above data when another apparatus is used.

Thereafter, a copper seed layer 109 made of a copper film is deposited with a thickness of 30 nm on the second barrier metal 108 by, for example, a sputtering method. Respective bottoms and sidewalls of the via hole 106 and the interconnection groove 107 are thus covered by the second barrier metal 108 and the copper seed layer 109.

As shown in FIG. 1(c), a copper plating layer 110 is then grown with a thickness of 300 nm on the copper seed layer 109 by an electroplating method so as to fill the via hole 106 and the interconnection groove 107.

Thereafter, the semiconductor substrate 100 is removed from a plating apparatus, and the copper plating layer 110 is heat treated (for example, at about 100° C. for about 2 hours) in order to grow crystal grains of the copper plating layer 110. As a result, as shown in FIG. 1(d), the copper seed layer 109 and the copper plating layer 110 are integrated to form an interconnection copper film 111. Note that, instead of performing the above-described heat treatment to the copper plating layer 110, the semiconductor substrate 100 may be left at room temperature for about two days.

As shown in FIG. 1(e), the second barrier metal 108 and interconnection copper film 111 located outside the interconnection groove 107 are removed by, for example, a CMP (Chemical Mechanical Polishing) method to form a via 112 and a second interconnect 113 from the interconnection copper film 111. The first interconnect 103 and the second interconnect 113 are thus connected to each other through the via 112.

Although not shown in the figure, a desired multilayer interconnect structure is formed as necessary by repeating the process described using the cross-sectional views of FIGS. 1(a) through 1(e) (regarding the process described using the cross-sectional view of FIG. 1(a), the step of depositing the first silicon nitride film 104 and the following steps).

As has been described above, according to the first embodiment, the second barrier metal 108 partially including an amorphous structure having a relatively high barrier property can be formed on the respective bottoms and sidewalls of the via hole 106 and interconnection groove 107. The barrier property is thus improved and copper diffusion can be prevented. Since the second barrier metal 108 is a single layer, reduction in thickness of the second barrier metal 108 (10 nm or less) can be more easily controlled than a barrier metal having a layered structure.

Note that, in the first embodiment, ruthenium is used as a material of the second barrier metal 108. However, ruthenium, rhodium, palladium, osmium, iridium, platinum, an alloy of these metals, or the like, may alternatively be used.

In the first embodiment, pure copper is used as a material of the first interconnect 103, the copper seed layer 109, or the copper plating layer 110. However, a copper alloy may alternatively be used.

In the first embodiment, a ruthenium film is used as the first barrier metal 102. However, a tantalum film, a tantalum nitride film or the like may alternatively be used.

In the first embodiment, a silicon dioxide film, a coating film, a carbon-containing, low-dielectric-constant film or the like may be used as the first insulating film 101 or the second insulating film 105.

A dual damascene method for simultaneously filling the via hole 106 and the interconnection groove 107 with a conductive film is used in the first embodiment. However, the via hole 106 and the interconnection groove 107 may alternatively be formed separately and a conductive film may be separately buried in the via hole 106 and the interconnection groove 107.

In the first embodiment, the heat treatment for forming the interconnection copper film 111 may be performed in a nitrogen atmosphere. This can suppress crystallization of the second barrier metal 108 partially including an amorphous structure having a relatively high barrier property. Performing such heat treatment in a nitrogen atmosphere is therefore more effective to improve the barrier property.

In the first embodiment, nitrogen may be added by ion implantation after formation of the second barrier metal 108.

### Second Embodiment

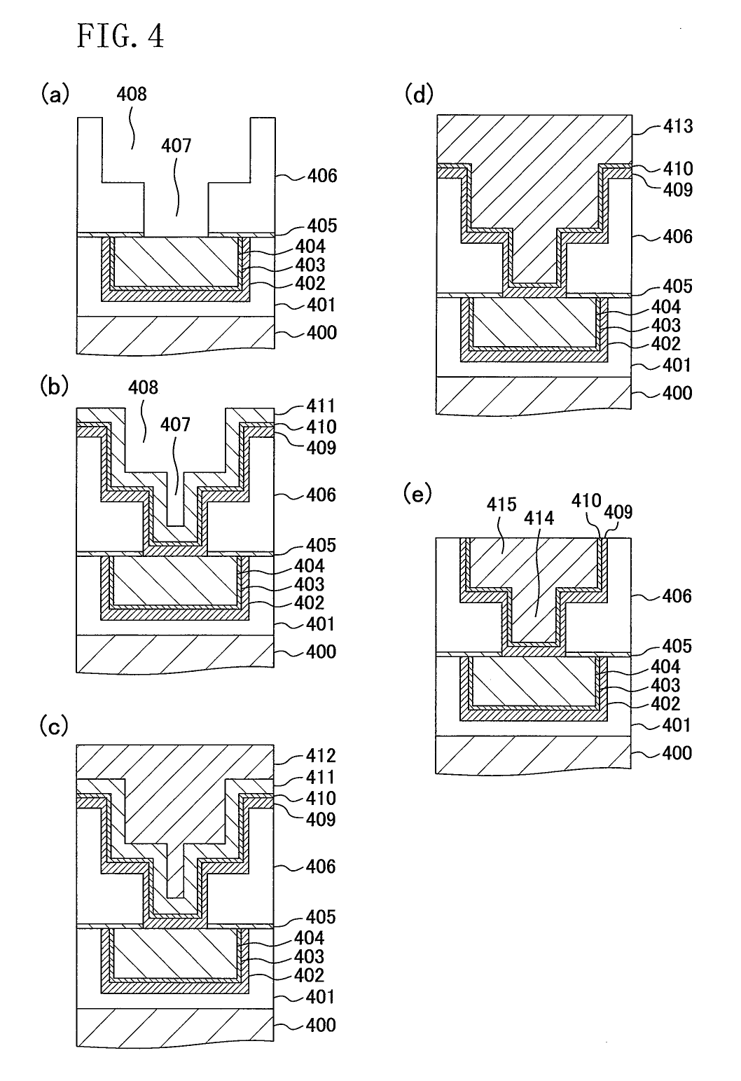

Hereinafter, a second embodiment of the invention will be described with reference to FIGS. 4(a) through 4(e), 2, and 3. FIGS. 4(a) through 4(e) are cross-sectional views illustrating each step of a method for manufacturing a semiconductor device according to the second embodiment of the invention.

First, as shown in FIG. 4(a), a first interconnect 404 made of, for example, a copper film is buried in a groove of a first insulating film 401 on a semiconductor substrate 400 through a first barrier metal 402 made of, for example, a ruthenium film partially including an amorphous structure having a relatively high barrier property and a second barrier metal 403 made of, for example, a polycrystalline ruthenium film. A first silicon nitride film 405 and a second insulating film 406 are then sequentially deposited over the semiconductor substrate 400, and a via hole 407 and an interconnection groove 408 are formed in the first silicon nitride film 405 and the second insulating film 406 so as to reach the first interconnect 404. At this time, the first barrier metal 402, the second barrier metal 403, or the first silicon nitride film 405 prevents copper atoms of the first interconnect 404 from diffusing into the first insulating film 401, the second insulating film 406 or the like by heat treatment at about 400° C. for depositing the second insulating film 406 (for example, a plasma CVD (Chemical Vapor Deposition) method). In other words, the first barrier metal 402, the second barrier metal 403, or the first silicon nitride film 405 has a barrier property against copper atom diffusion.

As shown in FIG. 4(b), a third barrier metal 409 made of a single layer of ruthenium or ruthenium alloy is then deposited with a thickness of 5 nm over the semiconductor substrate 400 by, for example, a sputtering method. At this time, ruthenium is used as a sputtering target and nitrogen is contained in a sputtering atmosphere.

More specifically, as described in the first embodiment with reference to FIGS. 2 and 3, a barrier metal including an amorphous structure having a high barrier property can be formed when a nitride partial pressure during sputtering is 50% or higher. Note that a material that is contained in the third barrier metal 409 is not limited to nitrogen as long as a film including an amorphous structure can be formed. As described in the first embodiment, the single-layer third barrier metal 409 partially including an amorphous structure preferably has a nitrogen concentration of 2% to 10%, and more preferably, 4% to 10%.

Thereafter, a fourth barrier metal 410 made of ruthenium is deposited with a thickness of 5 nm by a sputtering method. At this time, ruthenium is used as a sputtering target, and the nitrogen partial pressure during sputtering is lower than that used when the third barrier metal 409 is deposited.

A copper seed layer 411 made of a copper film is then deposited with a thickness of 30 nm on the fourth barrier metal 410 by, for example, a sputtering method. Respective bottoms and sidewalls of the via hole 407 and the interconnection groove 408 are thus covered by the third barrier metal 409, the fourth barrier metal 410, and the copper seed layer 411.

As shown in FIG. 4(c), a copper plating layer 412 is then grown with a thickness of 300 nm on the copper seed layer 411 by an electroplating method so as to fill the via hole 407 and the interconnection groove 408.

Thereafter, the semiconductor substrate 400 is removed from a plating apparatus, and the copper plating layer 412 is heat treated (for example, at about 100° C. for about 2 hours) in order to grow crystal grains of the copper plating layer 412. As a result, as shown in FIG. 4(d), the copper seed layer 411 and the copper plating layer 412 are integrated to form an interconnection copper film 413. Note that, instead of performing the above-described heat treatment to the copper plating layer 412, the semiconductor substrate 400 may be left at room temperature for about two days.

As shown in FIG. 4(e), the third barrier metal 409, fourth barrier metal 410, and interconnection copper film 413 located outside the interconnection groove 408 are removed by, for example, a CMP (Chemical Mechanical Polishing) method to form a via 414 and a second interconnect 415 from the interconnection copper film 413. The first interconnect 404 and the second interconnect 415 are thus connected to each other through the via 414.

Although not shown in the figure, a desired multilayer interconnect structure is formed as necessary by repeating the process described using the cross-sectional views of FIGS. 4(a) through 4(e) (regarding the process described using the cross-sectional view of FIG. 4(a), the step of depositing the first silicon nitride film 405 and the following steps).

As has been described above, according to the second embodiment, the third barrier metal 409 partially including an amorphous structure having a relatively high barrier property can be formed on the respective bottoms and sidewalls of the via hole 407 and interconnection groove 408. The barrier property is thus improved and copper diffusion can be prevented. In the case where the third barrier metal 409 and the fourth barrier metal 410 are made of the same metal or the same alloy, the third barrier metal 409 and the fourth barrier metal 410 can be deposited in the same chamber.

Note that, in the second embodiment, ruthenium is used as a material of the third barrier metal 409 and the fourth barrier metal 410. However, ruthenium, rhodium, palladium, osmium, iridium, platinum, an alloy of these metals, or the like, may alternatively be used.

In the second embodiment, pure copper is used as a material of the first interconnect 404, the copper seed layer 411, or the copper plating layer 412. However, a copper alloy may alternatively be used.

In the second embodiment, an amorphous ruthenium film and a polycrystalline ruthenium film are used as the first barrier metal 402 and the second barrier metal 403, respectively. However, a tantalum film, a tantalum nitride film, or the like may alternatively be used.

In the second embodiment, a silicon dioxide film, a coating film, a carbon-containing, low-dielectric-constant film or the like may be used as the first insulating film 401 or the second insulating film 406.

A dual damascene method for simultaneously filling the via hole 407 and the interconnection groove 408 with a conductive film is used in the second embodiment. However, the via hole 407 and the interconnection groove 408 may alternatively be formed separately and a conductive film may be separately buried in the via hole 407 and the interconnection groove 408.

In the second embodiment, the heat treatment for forming the interconnection copper film 413 may be performed in a nitrogen atmosphere. This can suppress crystallization of the third barrier metal 409 partially including an amorphous structure having a relatively high barrier property. Performing such heat treatment in a nitrogen atmosphere is therefore more effective to improve the barrier property.

In the second embodiment, nitrogen may be added by ion implantation after formation of the third barrier metal 409.

### Third Embodiment

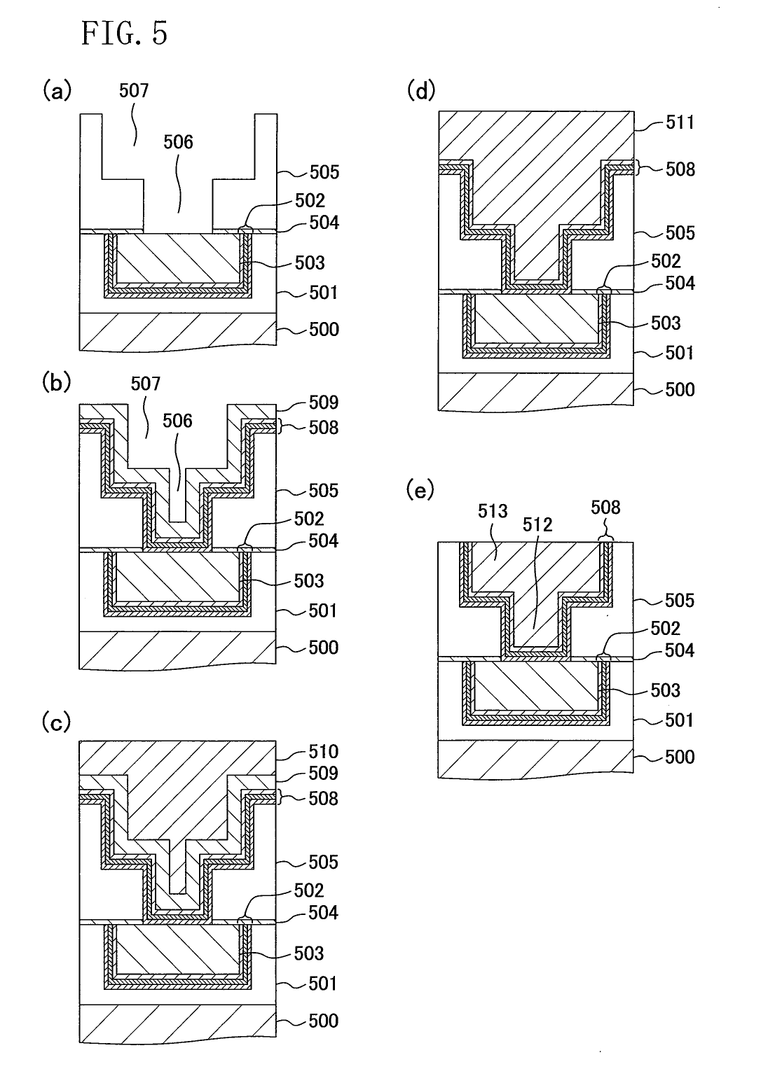

Hereinafter, a third embodiment of the invention will be described with reference to FIGS. 5(a) through 5(e), 2, and 3. FIGS. 5(a) through 5(e) are cross-sectional views illustrating each step of a method for manufacturing a semiconductor device according to the third embodiment of the invention.

First, as shown in FIG. 5(a), a first interconnect 503 made of, for example, a copper film is buried in a groove of a first insulating film 501 on a semiconductor substrate 500 through a first barrier metal 502 having a degree of amorphousness reduced stepwise from the first insulating film 501 to the first interconnect 503 from a layer partially including an amorphous structure having a relatively high barrier property. Such a first barrier metal 502 is formed by, for example, performing a sputtering method in a nitrogen atmosphere while reducing a nitrogen partial pressure stepwise. A first silicon nitride film 504 and a second insulating film 505 are then sequentially deposited over the semiconductor substrate 500, and a via hole 506 and an interconnection groove 507 are formed in the first silicon nitride film 504 and the second insulating film 505 so as to reach the first interconnect 503. At this time, the first barrier metal 502 or the first silicon nitride film 504 prevents copper atoms of the first interconnect 503 from diffusing into the first insulating film 501, the second insulating film 505 or the like by heat treatment at about 400° C. for depositing the second insulating film 505 (for example, a plasma CVD (Chemical Vapor Deposition) method). In other words, the first barrier metal 502 and the first silicon nitride film 504 have a barrier property against copper atom diffusion.

As shown in FIG. 5(b), a third barrier metal 508 made of a single layer of ruthenium is then deposited with a thickness of 10 nm over the semiconductor substrate 500 by, for example, a sputtering method. At this time, ruthenium is used as a sputtering target and nitrogen is contained in a sputtering atmosphere.

More specifically, as described in the first embodiment with reference to FIGS. 2 and 3, a barrier metal including an amorphous structure having a high barrier property can be formed when a nitride partial pressure during sputtering is 50% or higher. Note that a material that is contained in the second barrier metal 508 is not limited to nitrogen as long as a film including an amorphous structure can be formed.

The second barrier metal 508 having a degree of amorphousness reduced stepwise from a value having a relatively high barrier property, that is, the second barrier metal 508 having a degree of amorphousness reduced stepwise from a layer partially including an amorphous structure having a relatively high barrier property, can be formed by reducing the nitrogen partial pressure stepwise during deposition of the second barrier metal 508. For example, the second barrier metal 508 is formed by depositing a material of the second barrier metal 508 for 2 seconds at a nitrogen partial pressure of 90%, for 2 seconds at a nitrogen partial pressure of 80%, and then for 2 seconds at a nitrogen partial pressure of 60%. As in the first embodiment, the second barrier metal 508 partially including an amorphous structure preferably has a nitrogen concentration of 2% to 10%, and more preferably, 4% to 10%.

Thereafter, a copper seed layer 509 made of a copper film is deposited with a thickness of 30 nm on the second barrier metal 508 by, for example, a sputtering method. Respective bottoms and sidewalls of the via hole 506 and the interconnection groove 507 are thus covered by the second barrier metal 508 and the copper seed layer 509.

As shown in FIG. 5(c), a copper plating layer 510 is then grown with a thickness of 300 nm on the copper seed layer 509 by an electroplating method so as to fill the via hole 506 and the interconnection groove 507.

Thereafter, the semiconductor substrate 500 is removed from a plating apparatus, and the copper plating layer 510 is heat treated (for example, at about 100° C. for about 2 hours) in order to grow crystal grains of the copper plating layer 510. As a result, as shown in FIG. 5(d), the copper seed layer 509 and the copper plating layer 510 are integrated to form an interconnection copper film 511. Note that, instead of performing the above-described heat treatment to the copper plating layer 510, the semiconductor substrate 500 may be left at room temperature for about two days.

As shown in FIG. 5(e), the second barrier metal 508 and interconnection copper film 511 located outside the interconnection groove 507 are removed by, for example, a CMP (Chemical Mechanical Polishing) method to form a via 512 and a second interconnect 513 from the interconnection copper film 511. The first interconnect 503 and the second interconnect 513 are thus connected to each other through the via 512.

Although not shown in the figure, a desired multilayer interconnect structure is formed as necessary by repeating the process described using the cross-sectional views of FIGS. 5(a) through 5(e) (regarding the process described using the cross-sectional view of FIG. 5(a), the step of depositing the first silicon nitride film 504 and the following steps).

As has been described above, according to the third embodiment, the second barrier metal 508 having a degree of amorphousness reduced stepwise from a layer partially including an amorphous structure having a relatively high barrier property can be formed on the respective bottoms and sidewalls of the via hole 506 and interconnection groove 507. The barrier property is thus improved and copper diffusion can be prevented. Since the second barrier metal 508 can be deposited by controlling the amount of nitrogen gas in the same chamber, control for reduction in thickness (10 nm or less) can be easily implemented.

Note that, in the third embodiment, ruthenium is used as a material of the second barrier metal 508. However, ruthenium, rhodium, palladium, osmium, iridium, platinum, an alloy of these metals, or the like, may alternatively be used.

In the third embodiment, pure copper is used as a material of the first interconnect 503, the copper seed layer 509, or the copper plating layer 510. However, a copper alloy may alternatively be used.

In the third embodiment, a ruthenium film is used as the first barrier metal 502. However, a tantalum film, a tantalum nitride film, or the like may alternatively be used.

In the third embodiment, a silicon dioxide film, a coating film, a carbon-containing, low-dielectric-constant film or the like may be used as the first insulating film 501 or the second insulating film 505.

A dual damascene method for simultaneously filling the via hole 506 and the interconnection groove 507 with a conductive film is used in the third embodiment. However, the via hole 506 and the interconnection groove 507 may alternatively be formed separately and a conductive film may be separately buried in the via hole 506 and the interconnection groove 507.

In the third embodiment, the heat treatment for forming the interconnection copper film 511 may be performed in a nitrogen atmosphere. This can suppress crystallization of the second barrier metal 508 having an amorphous structure. Performing such heat treatment in a nitrogen atmosphere is therefore more effective to improve the barrier property.

In the third embodiment, nitrogen may be added by ion implantation after formation of the second barrier metal 508.

### Fourth Embodiment

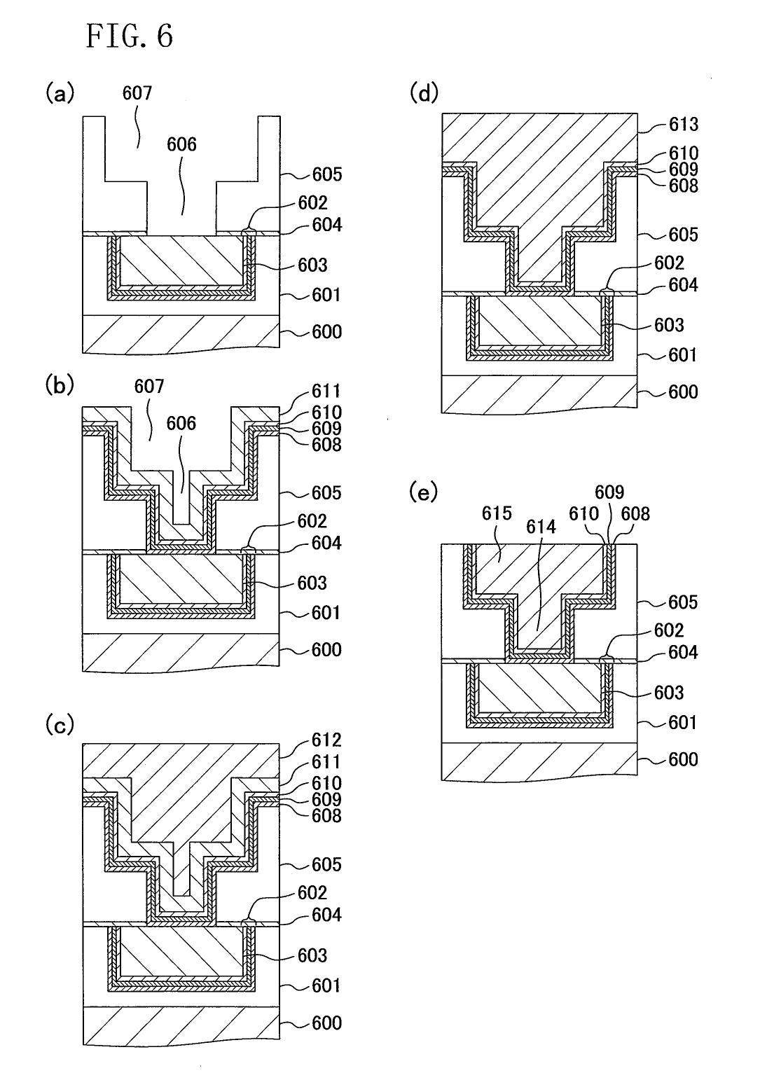

Hereinafter, a fourth embodiment of the invention will be described with reference to FIGS. 6(a) through 6(e). FIGS. 6(a) through 6(e) are cross-sectional views illustrating each step of a method for manufacturing a semiconductor device according to the fourth embodiment of the invention.

First, as shown in FIG. 6(a), a first interconnect 603 made of, for example, a copper film is buried in a groove of a first insulating film 601 on a semiconductor substrate 600 through a first barrier metal layer 602 made of, for example, a polycrystalline ruthenium film, a ruthenium film partially including an amorphous structure having a relatively high barrier property, and a polycrystalline ruthenium film. A first silicon nitride film 604 and a second insulating film 605 are then sequentially deposited over the semiconductor substrate 600, and a via hole 606 and an interconnection groove 607 are formed in the first silicon nitride film 604 and the second insulating film 605 so as to reach the first interconnect 603. At this time, the first layered barrier metal 602 or the first silicon nitride film 604 prevents copper atoms of the first interconnect 603 from diffusing into the first insulating film 601, the second insulating film 605 or the like by heat treatment at about 400° C. for depositing the second insulating film 605 (for example, a plasma CVD (Chemical Vapor Deposition) method). In other words, the first barrier metal layer 602 or the first silicon nitride film 604 has a barrier property against copper atom diffusion.

As shown in FIG. 6(b), a second barrier metal 608 made of ruthenium is then deposited with a thickness of 3 nm over the semiconductor substrate 600 by, for example, a sputtering method. At this time, ruthenium is used as a sputtering target.

A third barrier metal 609 made of a single layer of ruthenium is then deposited with a thickness of 3 nm by, for example, a sputtering method. At this time, ruthenium is used as a sputtering target and nitrogen is contained in a sputtering atmosphere. More specifically, as described in the first embodiment with reference to FIGS. 2 and 3, a barrier metal including an amorphous structure having a high barrier property can be formed when a nitride partial pressure during sputtering is 50% or higher. Note that a material that is contained in the third barrier metal 609 is not limited to nitrogen as long as a film including an amorphous structure can be formed. As in the first embodiment, the single-layer third barrier metal 609 partially including an amorphous structure preferably has a nitrogen concentration of 2% to 10%, and more preferably, 4% to 10%.

Moreover, a fourth barrier metal 610 made of ruthenium is deposited with a thickness of 3 nm by a sputtering method. At this time, ruthenium is used as a sputtering target.

A copper seed layer 611 made of a copper film is then deposited with a thickness of 30 nm on the fourth barrier metal 610 by, for example, a sputtering method. Respective bottoms and sidewalls of the via hole 606 and the interconnection groove 607 are thus covered by the second barrier metal 608, the third barrier metal 609, the fourth barrier metal 610, and the copper seed layer 611.

As shown in FIG. 6(c), a copper plating layer 612 is then grown with a thickness of 300 nm on the copper seed layer 611 by an electroplating method so as to fill the via hole 606 and the interconnection groove 607.

Thereafter, the semiconductor substrate 600 is removed from a plating apparatus, and the copper plating layer 612 is heat treated (for example, at about 100° C. for about 2 hours) in order to grow crystal grains of the copper plating layer 612. As a result, as shown in FIG. 6(d), the copper seed layer 611 and the copper plating layer 612 are integrated to form an interconnection copper film 613. Note that, instead of performing the above-described heat treatment to the copper plating layer 612, the semiconductor substrate 600 may be left at room temperature for about two days.

As shown in FIG. 6(e), the second barrier metal 608, third barrier metal 609, fourth barrier metal 610, and interconnection copper film 613 located outside the interconnection groove 607 are removed by, for example, a CMP (Chemical Mechanical Polishing) method to form a via 614 and a second interconnect 615 from the interconnection copper film 613. The first interconnect 603 and the second interconnect 615 are thus connected to each other through the via 614.

Although not shown in the figure, a desired multilayer interconnect structure is formed as necessary by repeating the process described using the cross-sectional views of FIGS. 6(a) through 6(e) (regarding the process described using the cross-sectional view of FIG. 6(a), the step of depositing the first silicon nitride film 604 and the following steps).

As has been described above, according to the fourth embodiment, the third barrier metal 609 partially including an amorphous structure having a relatively high barrier property can be formed on the respective bottoms and sidewalls of the via hole 606 and interconnection groove 607. The barrier property is thus improved and copper diffusion can be prevented. By forming the second barrier metal 608 on the first interconnect 603 at the bottom of the via hole 606, an interface between a layer partially including an amorphous structure and copper is not generated at the connection portion between the via hole 606 and the first interconnect 603. Since a layer made of a polycrystalline structure of a platinum group element or a platinum group element alloy has higher activation energy than that of a layer partially including an amorphous structure, reliability can be improved. In the case where the second barrier metal 608, the third barrier metal 609, and the fourth barrier metal 610 are made of the same metal or the same alloy, the second barrier metal 608, the third barrier metal 609, and the fourth barrier metal 610 can be deposited in the same chamber.

Note that, in the fourth embodiment, ruthenium is used as a material of the second barrier metal 608, the third barrier metal 609, and the fourth barrier metal 610. However, ruthenium, rhodium, palladium, osmium, iridium, platinum, an alloy of these metals, or the like, may alternatively be used.

In the fourth embodiment, pure copper is used as a material of the first interconnect 603, the copper seed layer 611, or the copper plating layer 612. However, a copper alloy may alternatively be used.

In the fourth embodiment, a layered ruthenium film is used as the first barrier metal layer 602. However, a tantalum film, a tantalum nitride film, or the like may alternatively be used.

In the fourth embodiment, a silicon dioxide film, a coating film, a carbon-containing, low-dielectric-constant film or the like may be used as the first insulating film 601 or the second insulating film 605.

A dual damascene method for simultaneously filling the via hole 606 and the interconnection groove 607 with a conductive film is used in the fourth embodiment. However, the via hole 606 and the interconnection groove 607 may alternatively be formed separately and a conductive film may be separately buried in the via hole 606 and the interconnection groove 607.

In the fourth embodiment, the heat treatment for forming the interconnection copper film 613 may be performed in a nitrogen atmosphere. This can suppress crystallization of the third barrier metal 609 partially including an amorphous structure having a relatively high barrier property. Performing such heat treatment in a nitrogen atmosphere is therefore more effective to improve the barrier property.

In the fourth embodiment, instead of forming the third barrier metal 609 in a nitrogen-containing sputtering atmosphere, nitrogen may be added by ion implantation after a nitrogen-free third barrier metal 609 is formed. In this method as well, nitrogen can be contained in the third barrier metal 609. A barrier metal film including an amorphous structure having a relatively high barrier property as compared to a nitrogen-free barrier metal film can thus be formed. A material to be implanted into the third barrier metal 609 is not limited to nitrogen as long as a film including an amorphous structure can be formed.

In the fourth embodiment, the barrier metal layers may be deposited in the same chamber by performing a sputtering method while controlling the nitrogen flow rate. Such processing in a single chamber enables reduction in cost or improvement in processing capability. Moreover, controllability on reduction in thickness of the barrier metal layers is improved.

### Fifth Embodiment

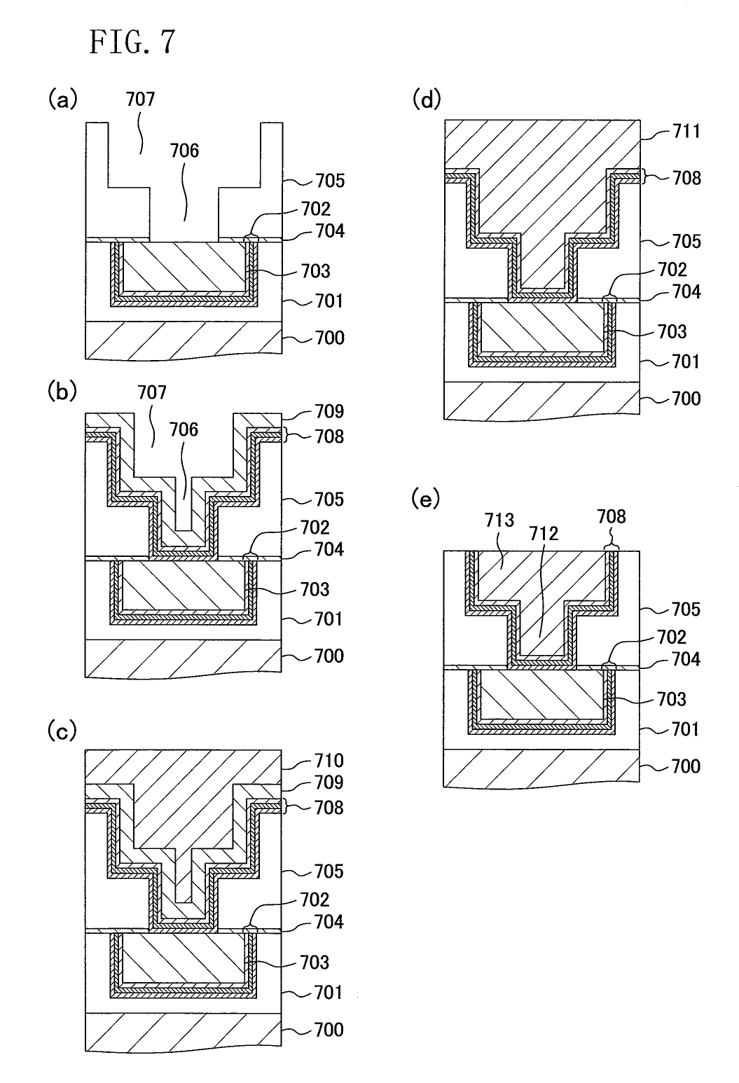

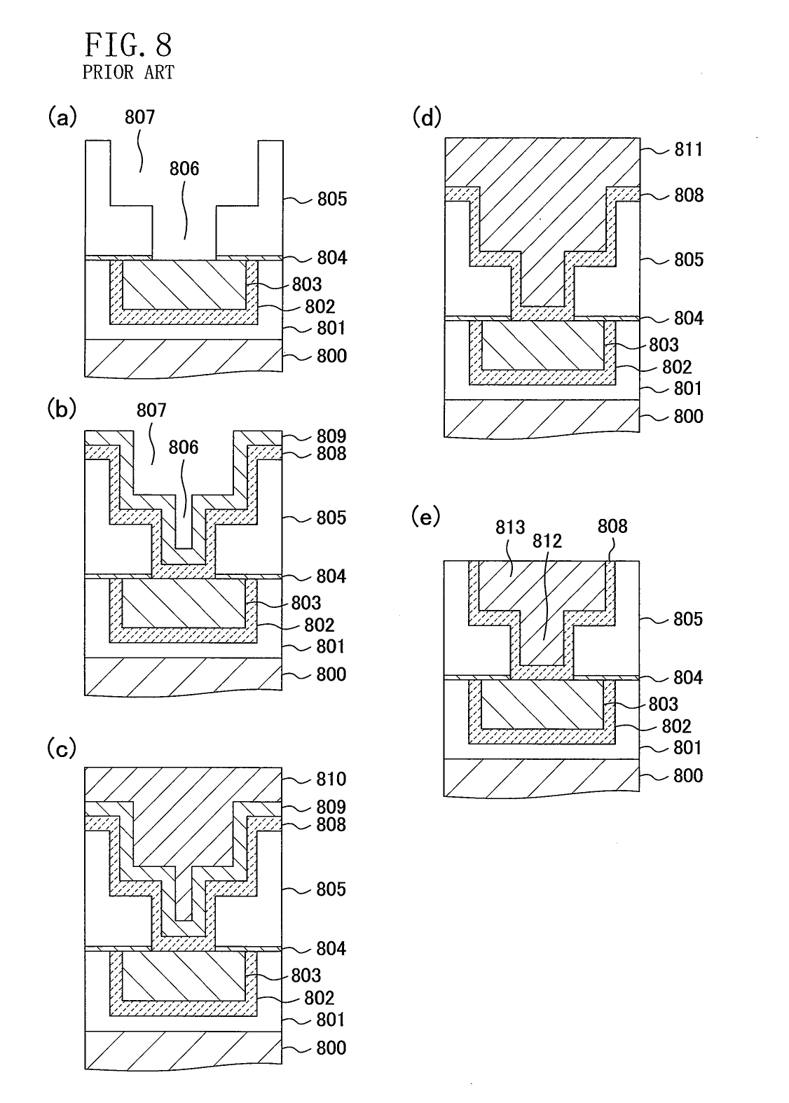

Hereinafter, a fifth embodiment of the invention will be described with reference to FIGS. 7(a) through 7(e). FIGS. 7(a) through 7(e) are cross-sectional views illustrating each step of a method for manufacturing a semiconductor device according to the fifth embodiment of the invention.

First, as shown in FIG. 7(a), a first barrier metal layer 702 is formed in a groove of a first insulating film 701 on a semiconductor substrate 700. The first barrier metal layer 702 has the following layers formed sequentially in a direction from the first insulating film 701 toward a first interconnect 703 in the following order: a layer having a first polycrystalline structure; a layer having a degree of amorphousness increased stepwise from the layer having a polycrystalline structure; a layer partially including an amorphous structure having a relatively high barrier property; a layer having a degree of amorphousness reduced stepwise from the layer partially including an amorphous structure having a relatively high barrier property; and a layer having a second polycrystalline structure. The first barrier metal layer 702 is formed by the following method: a layer having a first polycrystalline structure is first formed by a sputtering method using ruthenium as a sputtering target. Then, nitrogen is contained in a sputtering atmosphere, and a layer having a degree of amorphousness increased stepwise from the layer having a polycrystalline structure is formed by stepwise increasing a nitrogen partial pressure in the atmosphere. As a result, a layer partially including an amorphous structure having a relatively high barrier property as compared to the layer having a polycrystalline structure is formed eventually. Then, a layer having a degree of amorphousness reduced stepwise from the layer partially including an amorphous structure having a relatively high barrier property is formed by stepwise reducing the nitrogen partial pressure in the atmosphere. A layer having a second polycrystalline structure is formed as a result of reducing the degree of amorphousness. The first barrier metal layer 702 is thus formed.

Thereafter, a first interconnect 703 made of, for example, a copper film is buried in the groove of the first insulating film 501 through the first barrier metal layer 702. A first silicon nitride film 704 and a second insulating film 705 are then sequentially deposited over the semiconductor substrate 700, and a via hole 706 and an interconnection groove 707 are formed in the first silicon nitride film 704 and the second insulating film 705 so as to reach the first interconnect 703. At this time, the first barrier metal layer 702 or the first silicon nitride film 704 prevents copper atoms of the first interconnect 703 from diffusing into the first insulating film 701, the second insulating film 705 or the like by heat treatment at about 400° C. for depositing the second insulating film 705 (for example, a plasma CVD (Chemical Vapor Deposition) method). In other words, the first barrier metal layer 702 and the first silicon nitride film 704 have a barrier property against copper atom diffusion.

As shown in FIG. 7(b), a second barrier metal layer 708 made of a single layer of ruthenium or a ruthenium alloy is then deposited with a thickness of 10 nm over the semiconductor substrate 700 by, for example, a sputtering method. At this time, ruthenium is used as a sputtering target and nitrogen is contained in a sputtering atmosphere. More specifically, as described in the first embodiment with reference to FIGS. 2 and 3, a barrier metal including an amorphous structure having a high barrier property can be formed when a nitride partial pressure during sputtering is 50% or higher. Note that a material that is contained in the second barrier metal 708 is not limited to nitrogen as long as a film including an amorphous structure can be formed.

In this embodiment, a third barrier metal 709 is formed by controlling a nitrogen partial pressure in a stepwise manner so that the degree of amorphousness is increased stepwise from a value having a polycrystalline structure to a value having a relatively high barrier property and is reduced stepwise from the value having a relatively high barrier property to a value having a second polycrystalline structure. More specifically, a layer having a first polycrystalline structure is first formed by depositing a material for three seconds at a nitrogen partial pressure of 0%. Then, a layer having a degree of amorphousness increased stepwise from the layer having a polycrystalline structure is formed by stepwise increasing the nitrogen partial pressure to 90% in three seconds. As a result, a layer including an amorphous structure having a relatively high barrier property as compared to the layer having a polycrystalline structure is formed eventually. Then, a layer having a degree of amorphousness reduced stepwise from the layer including an amorphous structure having a relatively high barrier property is formed by stepwise reducing the nitrogen partial pressure to 0% in three seconds. A layer having a second polycrystalline structure is formed as a result of reducing the degree of amorphousness. The single-layer second barrier metal layer 708 can be formed by the above process. A film including an amorphous structure having a relatively high barrier property as compared to a nitrogen-free barrier metal film can be formed by controlling the nitrogen partial pressure in the barrier metal film in a stepwise manner. Note that a material that is contained in the barrier metal film is not limited to nitrogen as long as a film including an amorphous structure can be formed. As in the first embodiment, the second barrier metal layer 708 partially including an amorphous structure preferably has a nitrogen concentration of 2% to 10%, and more preferably, 4% to 10%.

Thereafter, a copper seed layer 709 made of a copper film is deposited with a thickness of 30 nm on the second barrier metal layer 708 by, for example, a sputtering method. Respective bottoms and sidewalls of the via hole 706 and the interconnection groove 707 are thus covered by the second barrier metal layer 708 and the copper seed layer 709.

As shown in FIG. 7(c), a copper plating layer 710 is then grown with a thickness of 300 nm on the copper seed layer 709 by an electroplating method so as to fill the via hole 706 and the interconnection groove 707.

Thereafter, the semiconductor substrate 700 is removed from a plating apparatus, and the copper plating layer 710 is heat treated (for example, at about 100° C. for about 2 hours) in order to grow crystal grains of the copper plating layer 710. As a result, as shown in FIG. 7(d), the copper seed layer 709 and the copper plating layer 710 are integrated to form an interconnection copper film 711. Note that, instead of performing the above-described heat treatment to the copper plating layer 710, the semiconductor substrate 700 may be left at room temperature for about two days.

As shown in FIG. 7(e), the second barrier metal layer 708 and interconnection copper film 711 located outside the interconnection groove 707 are removed by, for example, a CMP (Chemical Mechanical Polishing) method to form a via 712 and a second interconnect 713 from the interconnection copper film 711. The first interconnect 703 and the second interconnect 713 are thus connected to each other through the via 712.

Although not shown in the figure, a desired multilayer interconnect structure is formed as necessary by repeating the process described using the cross-sectional views of FIGS. 7(a) through 7(e) (regarding the process described using the cross-sectional view of FIG. 7(a), the step of depositing the first silicon nitride film 704 and the following steps).

As has been described above, according to the fifth embodiment, the second barrier metal layer 708 partially including an amorphous structure having a relatively high barrier property can be formed on the respective bottoms and sidewalls of the via hole 706 and interconnection groove 707. The barrier property is thus improved and copper diffusion can be prevented. By forming the second barrier metal layer 708 on the first interconnect 703 at the bottom of the via hole 706, an interface between a layer partially including an amorphous structure and copper is not generated at the connection portion between the via hole 706 and the first interconnect 703. Since a layer made of a polycrystalline structure of a platinum group element or a platinum group element alloy has higher activation energy than that of a layer partially including an amorphous structure, reliability can be improved.

Note that, in the fifth embodiment, ruthenium is used as a material of the second barrier metal layer 708. However, ruthenium, rhodium, palladium, osmium, iridium, platinum, an alloy of these metals, or the like, may alternatively be used.

In the fifth embodiment, pure copper is used as a material of the first interconnect 703, the copper seed layer 709, or the copper plating layer 710. However, a copper alloy may alternatively be used.

In the fifth embodiment, a ruthenium film is used as the first barrier metal layer 702. However, a tantalum film, a tantalum nitride film, or the like may alternatively be used.

In the fifth embodiment, a silicon dioxide film, a coating film, a carbon-containing, low-dielectric-constant film or the like may be used as the first insulating film 701 or the second insulating film 705.

A dual damascene method for simultaneously filling the via hole 706 and the interconnection groove 707 with a conductive film is used in the fifth embodiment. However, the via hole 706 and the interconnection groove 707 may alternatively be formed separately and a conductive film may be separately buried in the via hole 706 and the interconnection groove 707.

In the fifth embodiment, the heat treatment for forming the interconnection copper film 711 may be performed in a nitrogen atmosphere. This can suppress crystallization of the second barrier metal layer 708 partially including an amorphous structure having a relatively high barrier property. Performing such heat treatment in a nitrogen atmosphere is therefore more effective to improve the barrier property.

In the fifth embodiment, the barrier metal layers may be deposited in the same chamber by performing a sputtering method while controlling the nitrogen flow rate. Such processing in a single chamber enables reduction in cost or improvement in processing capability. Moreover, controllability on reduction in thickness of the barrier metal layers is improved.

### INDUSTRIAL APPLICABILITY

A semiconductor device and a manufacturing method thereof according to the invention are useful as, for example, a semiconductor device that has an amorphous barrier metal of a platinum group element having a high barrier property and has a copper interconnect or a copper alloy interconnect.

1. A semiconductor device, comprising:
an insulating film formed on a semiconductor substrate; and
a buried interconnect formed in the insulating film and made of copper or a copper alloy, wherein
a barrier metal layer made of a platinum group element or a platinum group element alloy is formed between the insulating film and the buried interconnect, and
the barrier metal layer partially includes an amorphous structure having a degree of amorphousness that provides a relatively high barrier property.

2. The semiconductor device according to claim 1, wherein the barrier metal layer is a single layer.

3. The semiconductor device according to claim 1, wherein the barrier metal layer has a layered structure and has a layer partially including the amorphous structure and a polycrystalline structure layer.

4. The semiconductor device according to claim 3, wherein the layer partially including the amorphous structure and the polycrystalline structure layer are sequentially formed in this order in a direction from the insulating film toward the buried interconnect.

5. The semiconductor device according to claim 1, wherein the barrier metal layer is structured so that the degree of amorphousness that provides the relatively high barrier property is reduced stepwise in a direction from the insulating film toward the buried interconnect.

6. The semiconductor device according to claim 1, wherein the barrier metal layer sequentially includes a first polycrystalline structure layer, a layer partially including the amorphous structure, and a second polycrystalline structure layer in a direction from the insulating film toward the buried interconnect.

7. The semiconductor device according to claim 1, wherein the barrier metal layer is structured so that a degree of amorphousness is increased stepwise from a value having a first polycrystalline structure to the value that provides the relatively high barrier property and reduced stepwise from the value that provides the relatively high barrier property to a value having a second polycrystalline structure in a direction from the insulating film toward the buried interconnect.

8. The semiconductor device according to any one of claims 1 to 7, wherein the platinum group element is ruthenium, rhodium, palladium, osmium, iridium, or platinum.

9. A method for manufacturing a semiconductor device, comprising the steps of:
(a) forming a recess in an insulating film on a semiconductor substrate;
(b) depositing a barrier metal layer made of a platinum group element or a platinum group element alloy in the recess;
(c) sequentially depositing a first conductive film made of copper or a copper alloy on the barrier metal layer;
(d) growing a second conductive film made of copper or a copper alloy on the first conductive film so as to completely fill the recess; and
(e) integrating the first conductive film and the second conductive film to form a third conductive film and forming a buried interconnect from the third conductive film, wherein the barrier metal layer partially includes an amorphous structure having a degree of amorphousness that provides a relatively high barrier property.

10. The method for manufacturing a semiconductor device according to claim 9, wherein the step (b) includes the steps of (b1) depositing in the recess a first barrier metal layer that forms the barrier metal layer and is made of a platinum group element or a platinum group element alloy, and (b2) depositing on the first barrier metal layer a second barrier metal layer that forms the barrier metal layer and is made of a platinum group element or a platinum group element alloy, wherein the first barrier metal layer partially includes the amorphous structure having the degree of amorphousness that provides the relatively high barrier property, and the second barrier metal layer has a polycrystalline structure.

11. The method for manufacturing a semiconductor device according to claim 9, wherein the step (b) includes the steps of (b1) depositing in the recess a first barrier metal layer that forms the barrier metal layer and is made of a platinum group element or a platinum group element alloy, (b2) depositing on the first barrier metal layer a second barrier metal layer that forms the barrier metal layer and is made of a platinum group element or a platinum group element alloy, and (b3) depositing on the second barrier metal layer a third barrier metal layer that forms the barrier metal layer and is made of a platinum group element or a platinum group element alloy, wherein the second barrier metal layer partially includes the amorphous structure having the degree of amorphousness that provides the relatively high barrier property, and the first barrier metal layer and the third barrier metal layer have a polycrystalline structure.

12. The method for manufacturing a semiconductor device according to claim 9, wherein the step (b) includes the step of forming the barrier metal film so that the degree of amorphousness that provides the relatively high barrier property is reduced stepwise in a direction from the insulating film toward the buried interconnect.

13. The method for manufacturing a semiconductor device according to claim 9, wherein the step (b) includes the step of forming the barrier metal film so that a degree of amorphousness is increased stepwise from a value having a first polycrystalline structure to the value that provides the relatively high barrier property and reduced stepwise from the value that provides the relatively high barrier property to a value having a second polycrystalline structure in a direction from the insulating film toward the buried interconnect.

14. The method for manufacturing a semiconductor device according to any one of claims 9 to 13, wherein the platinum group element is ruthenium, rhodium, palladium, osmium, iridium, or platinum.

15. The method for manufacturing a semiconductor device according to any one of claims 9 to 14, wherein the step (e) includes the step of performing heat treatment in a nitrogen atmosphere.

16. The method for manufacturing a semiconductor device according to any one of claims 9 to 15, wherein the step (b) is performed in a same chamber by using a sputtering method while controlling a nitrogen flow rate.
